(19) United States
(12) Patent Application Publication
(10) Pub. No.: US 2004/0006729 A1
(43) Pub. Date: Jan. 8, 2004

(54) Hierarchical test methodology for multi-core chips

(76) Inventor: Rajesh Y. Pendurkar, Sunnyvale, CA (US)

Correspondence Address: WILLIAM L. PARADICE, III, 425 CALIFORNIA STREET, SUITE 900, SAN FRANCISCO, CA, 94104, US

(21) Appl. No.: 10/189,870

(22) Filed: Jul. 3, 2002

(51) Int. Cl. G01R 31/28

(52) U.S. Cl. 714/733

(57) ABSTRACT

A multi-core chip (MCC) having a plurality of processor cores includes a hierarchical testing architecture compliant with the IEEE 1149.1 Joint Test Action Group (JTAG) standard that leverages existing standard testing architectures within each processor core to allow for chip level access to schedule built-in self test (BIST) operations for the cores. The MCC includes boundary scan logic, a chip-level JTAG-compliant test access port (TAP) controller, a chip-level master BIST controller, and a test pin interface. Each processor core includes a JTAG-compliant TAP controller and one or more BIST enabled memory arrays. The chip TAP controller includes one or more user defined registers, including a core select register and a test mode register. The core select register stores a plurality of core select bits that select corresponding processor cores for BIST operations.

### BACKGROUND

1. Field of Invention

This invention relates generally to integrated circuit devices, and specifically to the testing of an integrated circuit device having a plurality of cores.

2. Description of Related Art

The continuing demand for increased computing power of microprocessors has led to the recent trend of core-based designs. In a core-based design, one or more pre-existing cores are integrated as cells onto a single integrated circuit (IC) known as a multi-core chip (MCC) to form a more complex circuit. Because the pre-existing cores have already been designed and verified, they may be replicated and interconnected to form more powerful circuits without incurring the time and expense of developing an entirely new next-generation circuit. For example, rather than designing an entirely new processor, semiconductor manufacturers may increase processor capabilities by replicating a number of existing processor cores within an MCC that may then be offered as the next generation processor.

A major design issue for complex IC's is testability. Today, most processors include a testing architecture compliant with the IEEE Standard 1149.1, also known as the Joint Test Action Group (JTAG) standard. The JTAG standard was created primarily to allow for the testing of interconnects between IC's mounted on a system board without directly accessing the pins of each IC. Each JTAG-compliant circuit includes a Test Access Port (TAP) controller, a number of dedicated test pins, and boundary scan logic that allows test patterns to be shifted in and out of the circuit for fault testing.

The JTAG architecture may also be used to access a circuit's built-in self test (BIST) logic after the circuit is mounted onto a system board. Typically, an enable signal is applied to the internal BIST logic via the TAP controller to activate the BIST logic to perform test operations of the circuit. Generally, the BIST logic includes a Test Pattern Generator that applies test patterns to the circuit under test. The test pattern is applied to the circuit under test, and the resultant output data is compared with an expected signature to determine whether the circuit passes or fails the test. For example, for logic devices such as processors and controllers, logical built-in self-test circuitry may be used to pass pseudo-random test patterns through logic gates to verify their correct operation. For memory arrays, memory built-in self-test circuitry may be used to apply test patterns through the memory array to verify their operation.

A recent technique for accessing individual cores of an MCC for testing is disclosed in U.S. Pat. No. 6,115,763, which describes an MCC system in which each core includes a core interface unit coupled to a service access port to allow various service operations to be initiated through the common service access port without using a large number of input/output (I/O) pins. However, because each core in the MCC described in U.S. Pat. No. 6,115,763 uses a specially designed core interface unit, pre-existing cores that have standard test architectures such as the JTAG architecture cannot be used in that MCC without modifying each core to include the new core interface unit. Any such modification to the pre-existing cores undesirably increases the time and expense required to bring the MCC to market. Thus, it would be desirable to be able to use unmodified, pre-existing cores in an MCC that provides chip-level access to standard internal core testing features.

### SUMMARY

A method and apparatus are disclosed that allow preexisting processor cores that have standard test architectures to be replicated on an MCC without modification in a manner that allows for chip level access to internal BIST circuitry in the processor cores. In accordance with the present invention, an MCC is disclosed that includes a hierarchical testing architecture compliant with the IEEE 1149.1 JTAG standard that leverages existing JTAG and BIST circuitry within each processor core to facilitate chip-level access to core-level test operations. In one embodiment, the MCC includes boundary scan logic, a chip-level TAP controller, a chip-level master BIST controller, a test pin interface, and a plurality of processor cores. Each processor core includes a TAP controller, a core-level master BIST controller, and one or more BIST-enabled memory arrays.

The chip TAP controller includes one or more user defined registers, and in one embodiment includes a core select register and a control mode register. The core select register stores a plurality of core select bits that indicate whether corresponding processor cores are selected for a BIST operation. The core select bits may be loaded into the chip TAP controller from either the test pin interface or the boundary scan logic. The control mode register stores algorithm mode bits that specify the type of BIST operation performed and a test mode bit that selects between concurrent and sequential core testing operations.

The chip master BIST controller receives a BIST instruction from either the test pin interface or the chip TAP controller and, in response to the core select bits and the control mode bits, schedules the BIST operation for selected processor cores. For one embodiment, the chip master BIST controller provides a BIST enable signal to each selected processor core. The selected processor cores perform the BIST operation on their memory arrays, and report the test results to the chip master BIST controller, which in turn outputs the results via the test pin interface or the chip TAP controller. For one embodiment, the core master BIST controller within each processor core schedules the BIST operation for the BIST-enabled memory arrays in the core in response to control signals provided by the chip master BIST controller.

In this manner, the hierarchical testing architecture of present embodiments allows numerous pre-existing processor cores replicated on an MCC to be tested using standard chip-level test architectures without altering the design of individual core architectures. As a result, MCC's of present embodiments may be fabricated without incurring the time and expense typically required to develop and verify a new or modified design, which in turn may reduce the time-to-market for such MCC's. The ability to be the first to offer increased processing capabilities may provide a distinct market advantage.

### BRIEF DESCRIPTION OF THE DRAWINGS

The features and advantages of the present invention are illustrated by way of example and are by no means intended to limit the scope of the present invention to the particular embodiments shown, and in which:

FIG. 1 is a block diagram illustrating a conventional JTAG testing architecture;

FIG. 2 is a state diagram for the test access port (TAP) controller of FIG. 1;

FIG. 3 is a block diagram of one embodiment of a multi-core chip (MCC) in accordance with the present invention;

FIG. 4 is a block diagram of one embodiment of the TAP controller of FIG. 3;

FIG. 5 is a block diagram of one embodiment of the processor core of FIG. 3;

FIG. 6A illustrates one embodiment of a core select register of the TAP controller of FIG. 4;

FIG. 6B illustrates one embodiment of a control mode register of the TAP controller of FIG. 4;

FIG. 6C illustrates one embodiment of an additional user defined register of the TAP controller of FIG. 4;

FIG. 7 is a flow chart illustrating hierarchical testing of an MCC in one embodiment of the present invention; and

FIG. 8 is a state diagram for the master BIST controller of FIG. 3.

Like reference numerals refer to corresponding parts throughout the drawing figures.

### DETAILED DESCRIPTION

Embodiments of the present invention are discussed below in the context of a monolithic multi-core chip (MCC). The interconnections between circuit elements or cores may be shown as buses or as single signal lines, where each of the buses may alternatively be a single signal line, and each of the single signal lines may alternatively be a bus. Further, the logic levels assigned to various signals in the description below are arbitrary, and therefore may be modified (e.g., reversed polarity) as desired. Accordingly, the present invention is not to be construed as limited to specific examples described herein but rather includes within its scope all embodiments defined by the appended claims.

Present embodiments allow for the implementation of various built-in self test (BIST) operations within unmodified, pre-existing cores of an MCC using either a dedicated test pin interface on the MCC or a standard JTAG test architecture provided on the MCC. The BIST operations implemented in the MCC may be well-known or proprietary, and may be controlled in a hierarchical manner to leverage existing JTAG and BIST circuitry within each core. In this manner, numerous pre-existing cores having their own JTAG and BIST circuitry may be replicated and interconnected to form an MCC that has increased processing power without modifying the cores' test architecture. In addition, the hierarchical testing approach of present embodiments allows the MCC to include any core that has a standard JTAG testing architecture, thereby providing compatibility with many different cores.

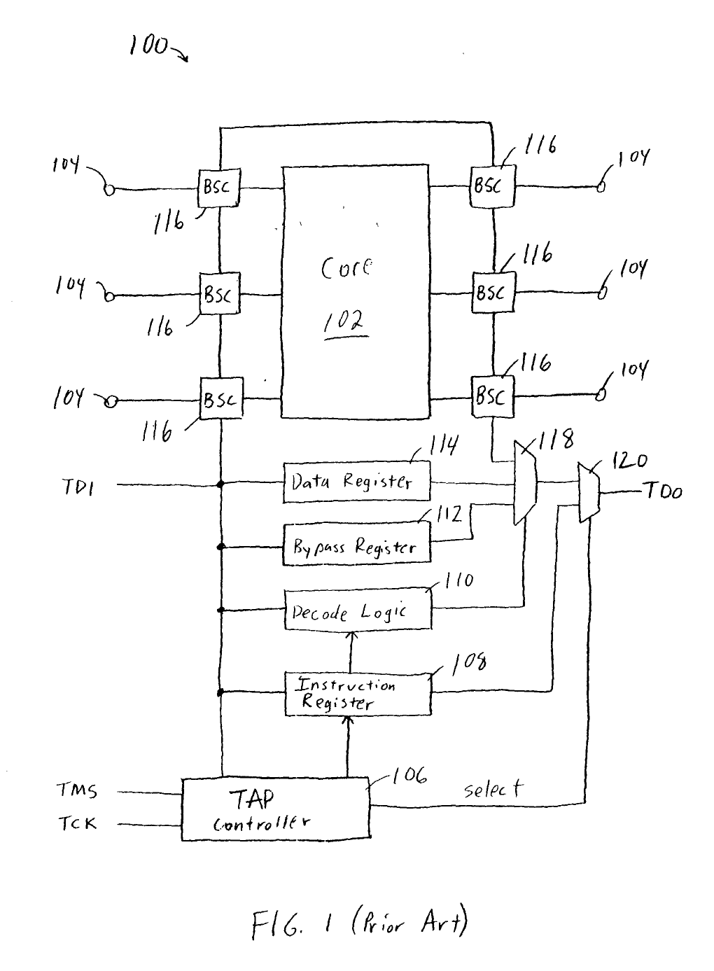

FIG. 1 illustrates a general integrated circuit 100 having a JTAG-compliant testing architecture. Circuit 100 includes core logic 102 and various input/output (I/O) pins 104. Core logic 102 may be any suitable logic core that performs one or more specified functions including, for example, a microprocessor having one or more memory arrays. The JTAG architecture permits internal scan, boundary scan, BIST operations, and other vendor specific design-for-testability (DFT) features for circuits and cores after they have been mounted onto a system board. The JTAG architecture includes a test access port (TAP) controller 106, an instruction register 108, decode logic 110, a set of test data registers including a bypass register 112, a data register 114, and a boundary scan register 116. Boundary scan register 116 includes a plurality of boundary scan cells (BSC) coupled between core 102 and corresponding I/O pins 104 to form a shift register that may be selectively connected between a test data in (TDI) pin and a test data out (TDO) pin via multiplexers 118 and 120. Instruction register 108 can be loaded with instructions related to various testing functions. Decode logic 110 decodes instructions in instruction register 108 and provides control signals to the data registers 112, 114 and to multiplexer 118. Multiplexer 118 is controller by decode logic 110. Multiplexer 120 is controller by TAP controller 106.

TAP controller 106 is a 16-state finite state machine controlled by a test mode signal (TMS) and a test clock (TCK), and may be coupled to an optional test reset (TRST) pin to facilitate resetting of TAP controller 106 (TRST not shown for simplicity). In general, data is loaded into the various data registers and instructions are loaded into instruction register 108 via the TDI pin. These instructions are decoded by decode logic 110 to enable various test operations such as, for example, scan tests, BIST operations, emulation, etc. Results of the tests may be read out of the data registers via the TDO pin.

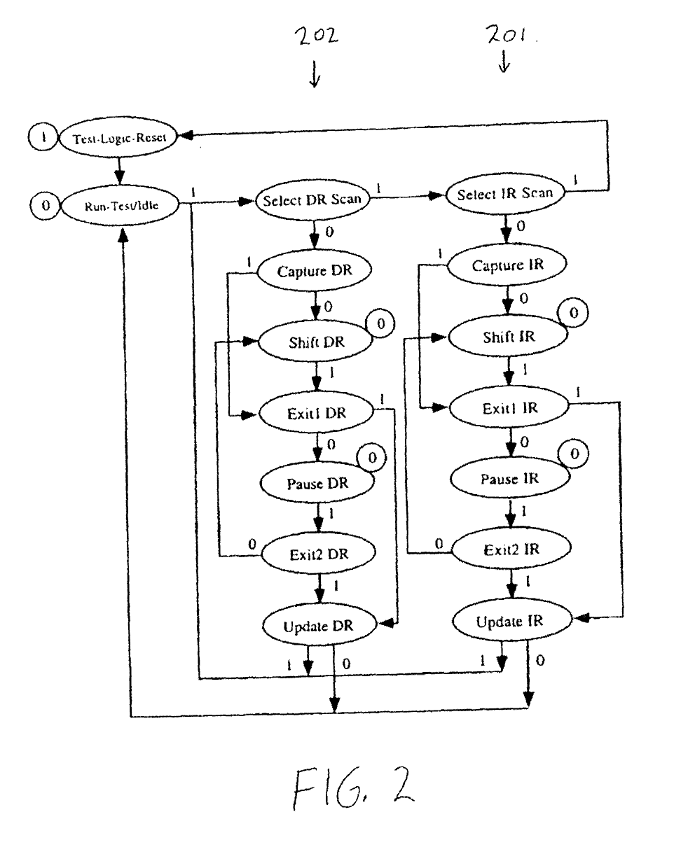

FIG. 2 illustrates a well-known state diagram for TAP controller 106 including a first state sequence 201 for loading instructions into instruction register 108 and a second state sequence 202 for loading data into selected data registers of circuit 100, as specified in the JTAG standard. TAP controller 106 is initially in the test-logic-reset state. TAP controller 106 remains in the test-logic-reset state while TMS is 1. If TMS is set to 0, then TAP controller 106 transits to the Run Test/Idle state. TAP controller 106 remains in the Run Test/Idle state while TMS remains 0. If TMS becomes 1, then TAP controller 106 transitions to the Select Data Register (DR) Scan state of state sequence 202. Data from TDI can be scanned into a selected data register in the Shift-DR state. The scan process can be paused by transitioning to the Pause DR state. The selected data register is updated during the Update DR state. If TMS is 0, then TAP controller 106 returns to the Run Test/Idle state. If TMS is 1, then TAP controller 106 returns to Select DR Scan state to access another data register. State sequence 201 permits instruction scanning into instruction register 108 in a similar manner. The details of this state diagram are not important to this invention. It is sufficient to note that for any particular implementation of a test access port controller, it is possible to place the JTAG interface into a mode to shift in data from TDI into any of the data registers and into the instruction register.

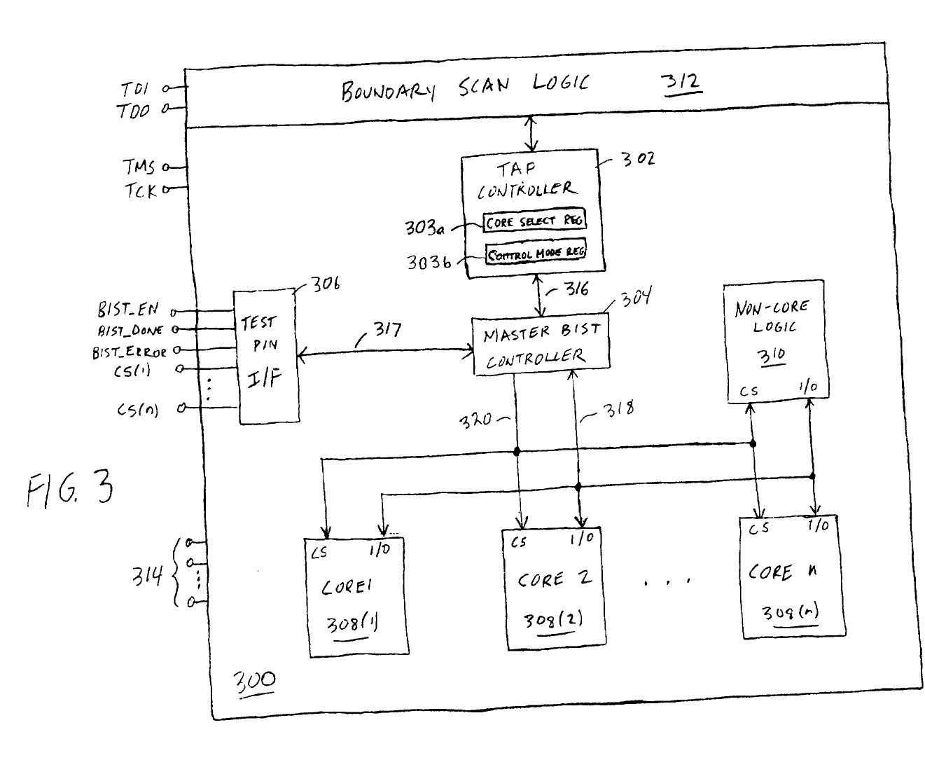

FIG. 3 shows a multi-core chip (MCC) 300 in accordance with the present invention. MCC 300 includes a standard chip-level TAP controller 302, a chip-level master BIST controller (chip MBC) 304, a test pin interface 306, a plurality of processor cores 308(1)-308(n), non-core logic 310, and boundary scan logic 312. Non-core logic may be any suitable logic. For one embodiment, non-core logic 310 includes one or more level-2 (L2) cache memories that are shared between processor cores 308(1)-308(n). MCC 300 also includes a plurality of I/O pins 314 for routing data, address, and control information to MCC 300. In addition, although not shown for simplicity, MCC 300 also includes power supply and ground pins.

For purposes of discussion herein, each processor core 308 is a well-known, pre-existing microprocessor that includes standard JTAG test circuitry and a plurality of internal, BIST-enabled memory arrays. For one embodiment, each processor core 308 is an existing microprocessor available from Sun Microsystems, Inc. For some embodiments, the processor cores 308 are cell designs that may be incorporated into the design and fabrication of MCC 300. For other embodiments, processor cores 308 are separate dice mounted on a common substrate using any well-known material and techniques. For other embodiments, each core 308 may be any suitable logic circuit including, for example, an application-specific integrated circuit (ASIC).

For one embodiment, the external pin-out of MCC 300 has the same footprint (including pin assignments and locations) of a similar type package housing individual processing core 308 so that customers presently using processor core 308 may easily increase processing power by substituting MCC 300 for processor core 308. In this manner, system boards do not have to be redesigned to accommodate a different package footprint.

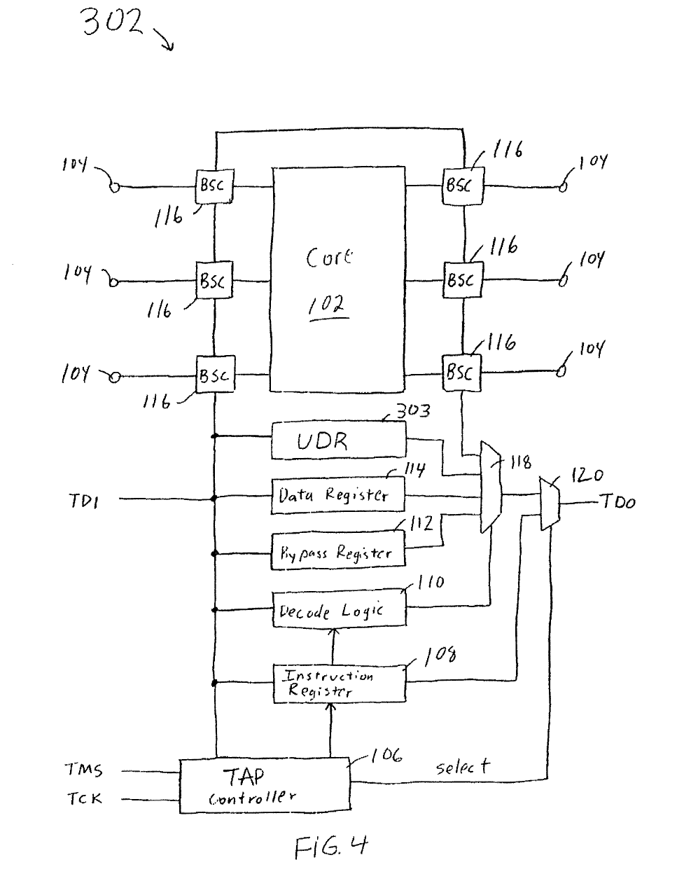

Chip TAP controller 302 is used to initiate BIST operations in selected processor cores 308(1)-308(n) when access to MCC 300's external pins is not readily available, e.g., after MCC 300 is mounted onto a system board. Chip TAP controller 302 is coupled to external TDI and TDO pins via well-known boundary scan logic 312, and also includes inputs to receive TMS and TCK from corresponding external pins. Chip TAP controller 302 is a JTAG-compliant TAP controller of the type shown in FIG. 1, and may receive the optional JTAG reset signal TRST (not shown for simplicity). In accordance with present embodiments, one or more additional user defined registers (UDRs) 303 are added to the conventional JTAG architecture allowed under the well-known “optional” clause of IEEE Standard 1149.1, as illustrated in FIG. 4.

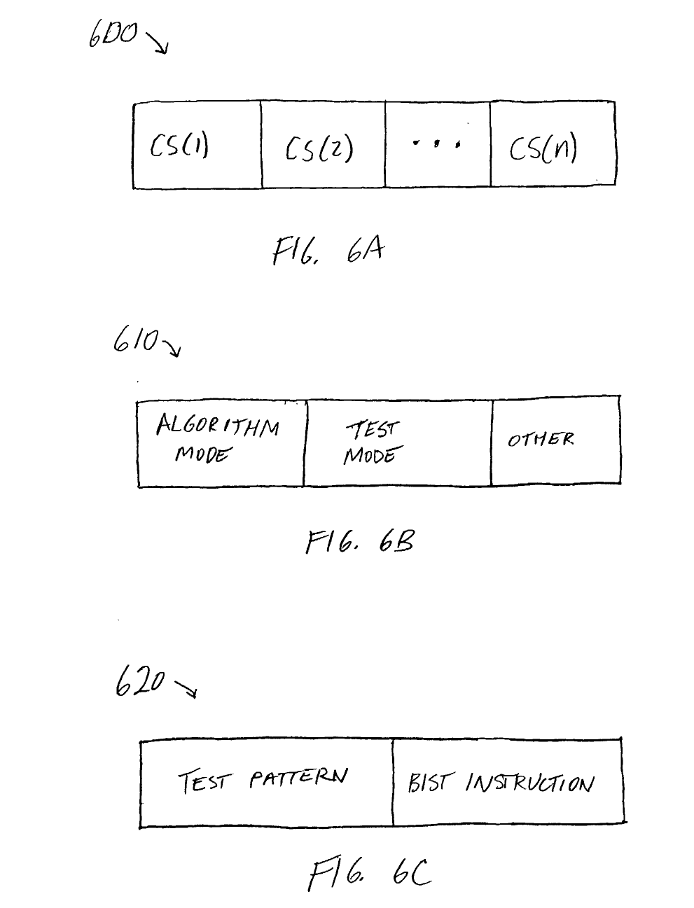

Referring again to FIG. 3, a first UDR 303a, hereinafter referred to as the core select register, stores a plurality of core select (CS) bits, each indicating whether a corresponding core 308 is enabled for a selected test operation. A second UDR 303b, hereinafter referred to as the control mode register, stores a number of algorithm mode bits that indicate which algorithm (e.g., a 6N or 13N March algorithm) the BIST operations performed in MCC 300 utilize, a test mode bit that indicates whether the BIST operation in cores 308 are performed concurrently or sequentially, and other control information. Core select register 303a and control mode register 303b may be loaded by scanning in appropriate signals to chip TAP controller 302 using boundary scan logic 312 according to the state diagram of FIG. 2. An exemplary embodiment 600 of core select register 303a is shown in FIG. 6a, and an exemplary embodiment 610 of control mode register is shown in FIG. 6B. For other embodiments, an additional UDR (not shown in FIG. 3 for simplicity) may be provided to store one or more specific BIST test patterns and/or instructions for implementing BIST operations in cores 308(1)-308(n). An exemplary embodiment 620 of this additional UDR for storing BIST test patterns and/or BIST instructions is shown in FIG. 6C.

Test pin interface 306 is used to initiate BIST operations in selected cores 308(1)-308(n) when MCC 300's external pins are available, e.g., before MCC 300 is mounted on a system board. Test pin interface 306 may be any well-known interface, and is coupled to a plurality of external core select pins CS(1)-CS(n) to receive CS signals corresponding to cores 308(1)-308(n), respectively. Test pin interface 306 is also coupled to test pins corresponding to BIST signals BIST_EN, BIST_DONE, and BIST_ERROR, where BIST_EN initiates an internal BIST operation in cores 308(1)-308(n) selected by chip MBC 304 in response to the CS signals, BIST_DONE indicates that the BIST operation is complete, and BIST_ERROR indicates an error condition for the BIST operation. For some embodiments, test pin interface 306 may be coupled to additional pins to receive other test-related signals. For other embodiments, test pin interface 306 may be eliminated.

Chip MBC 304 is coupled to chip TAP controller 302 via bus 316, to test pin interface 306 via bus 317, to an I/O terminal of each core 308 via bus 318, and to a core select (CS) input of each core 308 via bus 320. For other embodiments, buses 318 and 320 may be the same bus. Chip MBC 304 is a well-known finite state machine that schedules BIST operations for the various cores 308 in response to the BIST and CS signals, which as explained above may be provided by either chip TAP controller 302 or test pin interface 306. The specific logic used to implement chip MBC 304, which may differ between various embodiments, will be apparent to those skilled in the art after reading this disclosure, and thus is not provided herein so as to not unnecessarily obscure the invention. As explained below, chip MBC 304 may schedule BIST operations for selected processor cores 308(1)-308(n) in either a concurrent manner or in a sequential manner. For some embodiments, chip MBC 304 schedules BIST operations in cores 308 by routing the BIST signals (e.g., BIST_EN) only to selected cores 308(1)-308(n).

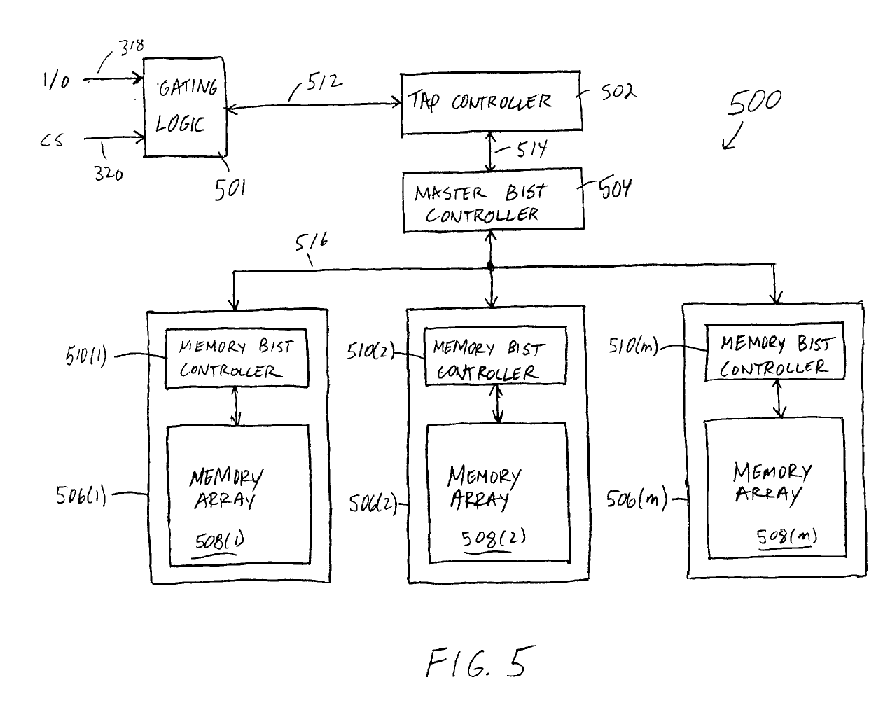

FIG. 5 shows a processor core 500 that is one embodiment of processor core 308 of FIG. 3. Core 500 includes gating logic 501, a standard core-level TAP controller 502, a core master BIST controller (core MBC) 504, and a plurality of testable memory elements 506(1)-506(m). For other embodiments, memory elements 506 may be testable circuit other than memory arrays such as, for example, logic circuits. Although not shown for simplicity, some embodiments of core 500 include dedicated inputs for the BIST signals (e.g., BIST_EN, BIST_DONE, and BIST_ERROR). Referring also to FIG. 3, gating logic 501 is coupled to bus 318 via core I/O inputs, to bus 320 via core CS inputs, and to core TAP controller 502 via bus 512. Gating logic 501 may be any well-known logic circuit that selectively passes BIST signals from chip MBC 304 to core TAP controller 502 in response to the CS signals provided by chip MBC 304. For one embodiment, gating logic 501 enables core 500 to receive the BIST signals from chip MBC 304 if the corresponding CS signal is asserted (e.g., to logic high), and disables core 500 during the BIST operation if the corresponding CS signal is un-asserted (e.g., to logic low). For some embodiments, gating logic 501 includes tri-stated inputs coupled to bus 318. For other embodiments, gating circuit 501 may be eliminated, and the enabling/disabling of cores 500 instead performed by chip MBC 304.

Core TAP controller 502 is a JTAG-compliant TAP controller of the type shown in FIG. 1, and is coupled to core MBC 504 via bus 514. BIST signals are routed between core TAP controller 502 and gating logic 501 using TDI and TDO (not shown for simplicity). For some embodiments, core TAP controller 502 is coupled to core TDI and TDO via core boundary scan logic (not shown for simplicity). For one embodiment, TMS and TCK are provided to TAP controller 502 of each core 500 simultaneously so that all core TAP controllers 502 are in the same state. For another embodiment, TMS and TCK are provided to each core TAP controller 502 by chip MBC 304, which in turn may independently transition the states of various core TAP controllers 502, for example, when scheduling sequential BIST operations for selected cores 500.

Core MBC 504, which is coupled to memory elements 506(1)-506(m) via a bus 516, is a well-known finite state machine that schedules BIST operations in core memory elements 506(1)-506(m) in response to BIST signals received from chip MBC 304 via core TAP controller 502. For one embodiment, core MBC 504 decodes the BIST control mode signals and, in response thereto, selectively asserts BIST_EN for core memory elements 506(1)-506(m) to initiate testing operations therein. Core MBC 504 may schedule either concurrent or sequential BIST operations in the corresponding core memory elements 506. The specific logic used to implement core MBC 504, which may differ between various embodiments, will be apparent to those skilled in the art after reading this disclosure, and thus is not provided herein so as to not unnecessarily obscure the invention. For some embodiments, chip MBC 304 and core MBC 504 are identical logic structures.

Each memory element 506 is a BIST-enabled memory structure that includes a memory array 508 coupled to a memory BIST controller 510. Memory array 508 may be any suitable type of memory array. For one embodiment, memory array 508 is a level-1 (L1) cache memory implemented as an SRAM device for the processor core. Memory BIST controller 510 is a well-known circuit that performs BIST operations of corresponding memory array 508 in response to the BIST_EN signal provided by core MBC 504. The precise manner of operation of performing and implementing a memory BIST operation is well-known in the art, and therefore is not described herein.

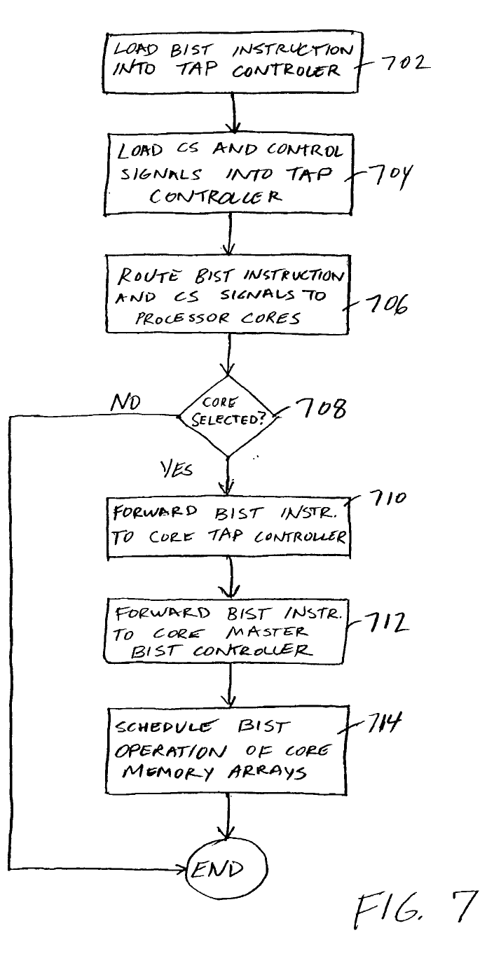

Operation of MCC 300 in performing a hierarchical BIST operation is described below with respect to the flow chart of FIG. 7, and to FIGS. 3 and 5. For purposes of discussion herein, chip TAP controller 302 is used to access the self-test features of MCC 300, for example, after MCC 300 is mounted onto a system board. However, as described above, test pin interface 306 may be used to access the self-test features of MCC 300 before MCC 300 is mounted onto the system board.

To initiate a memory BIST operation in selected processor cores 308(1)-308(n), a BIST instruction is loaded into chip TAP controller 302 via boundary scan logic 312 (step 702). The BIST instruction may be any well-known instruction that initiates a memory BIST operation. The core select (CS) signals and BIST control signals are loaded into core select register 303a and control mode register 303b, respectively, via boundary scan logic 312 (step 704). For one embodiment, an asserted CS signal (e.g., logic high) indicates that the corresponding core 308 will participate in the BIST operation, while an un-asserted CS signal (e.g., logic low) indicates that the corresponding core 308 will not participate in the BIST operation. For some embodiments, the BIST control signals may be included in the BIST instruction. For other embodiments, the BIST instruction may be a default instruction stored, for example, in the additional user defined register 620 of chip TAP controller 302.

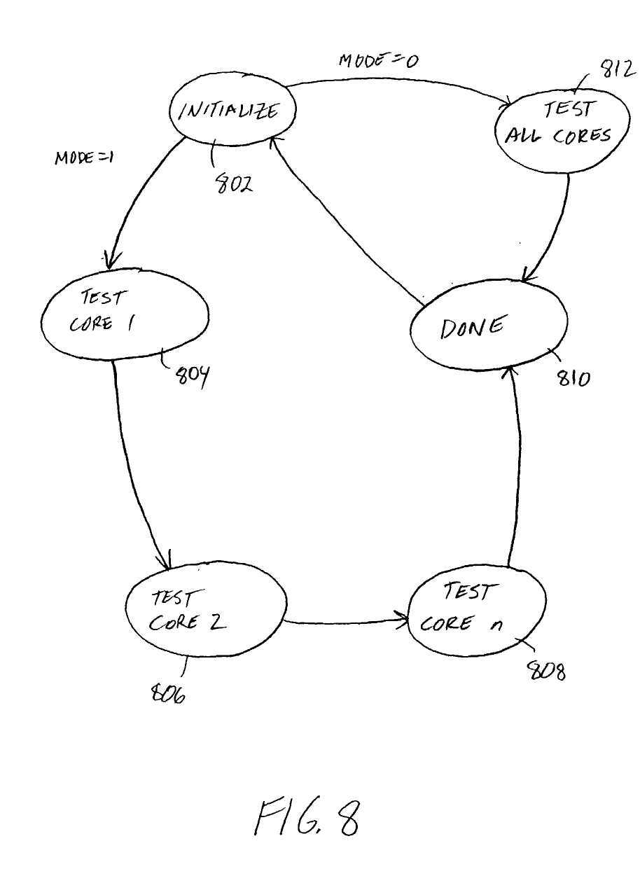

The BIST instruction and the BIST control signals are routed from chip TAP controller 302 to processor cores 308(1)-308(n) via chip MBC 304 (step 706). Chip MBC 304 schedules BIST operations in selected cores 308(1)-308(n) in response to the control mode bit. Referring also to the exemplary state diagram of FIG. 8, chip MBC 304 starts in an initial state 802. If the test mode bit indicates a concurrent mode (e.g., MODE=0), chip MBC 304 transitions to state 804 and simultaneously routes the BIST instruction and CS signals to all cores 308, which in turn may simultaneously perform core BIST operations, for example, to minimize testing time. When testing of the cores 308 is complete, chip MBC 304 transitions to state 810 to output the test results, and then returns to state 802.

If the test mode bit indicates a sequential mode, chip MBC 304 schedules BIST operations for the selected cores 308(1)-(n) in a sequential manner, for example, to reduce peak power consumption. Chip MBC 304 transitions to state 804 and initiates the BIST operation for core 1. When testing of core 1 is complete, chip MBC 304 transitions to state 806 and initiates the BIST operation for core 2, and so on, until the last core is tested in state 808. Chip MBC 304 transitions to state 810 to output the test results, and then returns to state 802. For other embodiments, the results of each core BIST operation may be reported back to chip MBC 304 during corresponding states 802, 804, and 806 of FIG. 8.

For each core 308, gating logic 501 selectively enables the core for the BIST operation in response to the CS signals, as tested in step 708. If the core 308 is not selected for testing, gating logic 501 does not forward the BIST instruction to the core TAP controller 502, and the core 308 does not participate in the BIST operation (step 710). Conversely, if the core 308 is selected for testing, gating logic 501 forwards the BIST instruction (e.g., BIST_EN) to the core TAP controller 502 (step 712). For some embodiments, gating logic 501 selectively enables and disables core TAP controller 502 in response to the CS signals. The core TAP controllers 502 of selected cores 308 forward the BIST instruction to the corresponding core MBCs 504 (step 714), which in turn schedule the BIST operation for the corresponding core memory elements 506(1)-506(m) (step 716).

For one embodiment, the core MBC 504 for each selected core 308 decodes the instruction received from chip MBC 304 and provides an asserted BIST_EN to the memory BIST controllers 510 in corresponding core memory elements 506. Memory BIST controllers 510 perform a well-known memory BIST operation on corresponding memory arrays 508 in response to BIST_EN received from core MBC 504. After testing, each memory BIST controller 510 returns a done signal and a pass/fail signal to chip MBC 304 via core MBC 504 and core TAP controller 502. The done signal indicates whether the test operation is complete, and the pass/fail signal indicates whether a fault is detected in the corresponding memory array.

Each memory BIST controller 510 includes an address generator for corresponding memory arrays 508. For one embodiment, the address generator may be a counter. For another embodiment, the address generator may be a pseudo-random linear feedback shift register (LFSR). Each memory BIST controller 510 may also include a test register to store test patterns that may be applied to memory array 508 during BIST operations. For some embodiments, the test register is a read only memory (ROM). For other embodiments, external test patterns may be loaded into memory BIST controllers 510 through chip TAP controller 302, chip MBC 304, core TAP controller 502, and core MBC 504. Test patterns read out of memory arrays 508 are compared with an expected result or signature in a well-known manner, for example, using comparators and multiple-input shift registers (MISR) provided within memory BIST controllers 510. If the output test patterns match the expected signature, the pass/fail signal is asserted to indicate the pass condition. Otherwise, the pass/fail signal is de-asserted to indicate the fail condition.

As mentioned above, for some embodiments, chip MBC 304 and core MBC 504 are identical structures. Thus, for these embodiments, each core MBC 504 may schedule testing of one or more selected corresponding core memory arrays 508 either sequentially or concurrently in a manner similar to that described above with respect to chip MBC 304. For one embodiment, core MBC 504 includes memory to store a core test mode bit for the corresponding core. For another embodiments, the core test mode bit may be provided to core MBC 504 by chip MBC 304 via the BIST instruction.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention. For example, although described in the context of memory BIST operations, embodiments of the present invention are equally applicable to performing logic BIST operations in a hierarchical manner on an MCC.

What is claimed is:

1. An integrated circuit having a hierarchical built-in self test (BIST) architecture, comprising:
a plurality of cores, each including:
a number of memory elements, each having a memory array coupled to a corresponding memory BIST controller;
a core-level master BIST controller coupled to each of the memory elements; and
a standard core-level test access port (TAP) controller coupled to the core master BIST controller;
a chip-level master BIST controller coupled to each of cores; and
a standard chip-level test access port (TAP) controller coupled to the chip-level master BIST controller and having a core select register for storing a plurality of core select bits, each indicating whether a corresponding core is selected for a BIST operation.

2. The integrated circuit of claim 1, wherein the chip-level master BIST controller schedules the BIST operation for the selected cores.

3. The integrated circuit of claim 2, wherein the core-level master BIST controllers schedule the BIST operation for corresponding memory elements in response to the core select bits.

4. The integrated circuit of claim 2, wherein the chip-level TAP controller further comprises a control mode register for storing a test mode bit indicating how the chip-level master BIST controller schedules the BIST.

5. The integrated circuit of claim 4, wherein the control mode register further stores an algorithm mode bit indicating which of a plurality of algorithms the BIST operation utilizes.

6. The integrated circuit of claim 2, wherein the chip-level TAP controller further comprises an additional test data register for storing a default BIST instruction.

7. The integrated circuit of claim 1, wherein the memory arrays comprises cache memory.

8. The integrated circuit of claim 1, wherein each core comprises a processor.

9. The integrated circuit of claim 1, wherein the chip-level TAP controller and the core-level TAP controllers are compliant with the Joint Test Action Group (JTAG) standard.

10. The integrated circuit of claim 1, further comprising:
a plurality of core select pins to receive the core select bits; and
a test pin interface coupled to the plurality of core select pins and to the chip-level master BIST controller.

11. The integrated circuit of claim 10, further comprising:
a plurality of BIST pins coupled to the test pin interface.

12. The integrated circuit of claim 1, wherein each core further comprises gating logic coupled between the chip-level master BIST controller and the corresponding core TAP controller, the gating logic selectively enabling the core for the BIST operation in response to the core select bits.

13. The integrated circuit of claim 1, wherein each of the cores comprises a pre-existing processor core having an identical pin-out configuration as the integrated circuit.

14. The integrated circuit of claim 1, wherein each of the cores comprises a processor core cell-based design.

15. A method of performing a built-in self test (BIST) operation in an integrated circuit having a plurality of processor cores, comprising:
loading a built-in self test (BIST) instruction into a chip-level test access port (TAP) controller;
loading a plurality of core select bits into a core select register of the chip-level TAP controller;
selectively enabling the processor cores for the BIST operation in response to the core select bits; and
scheduling the BIST operation for the selected processor cores using a chip-level master BIST controller.

16. The method of claim 15, wherein the selectively enabling comprises:
providing the core select bits to each processor core; and
decoding the core select bits to selectively enable a core TAP controller in the processor core.

17. The method of claim 15, wherein the scheduling comprises, for each selected processor core:
decoding the BIST instruction in a core master BIST controller to generate a BIST enable signal; and
implementing the BIST operation in response to the BIST enable signal using a memory BIST controller.

18. The method of claim 15, further comprising:
loading a test mode bit into a test mode register of the chip-level TAP controller, the test mode bit indicating whether the BIST operation is performed in the selected cores in a sequential manner or in a concurrent manner.

19. The method of claim 15, further comprising;
loading an algorithm mode bit into the test mode register of the chip-level TAP controller, the algorithm mode bit indicating which of a plurality of algorithms the BIST operation utilizes.

20. A multi-core chip (MCC) having a hierarchical test architecture, comprising:
a plurality of cores, each including means for implementing a core-level JTAG-compliant test interface;
means for implementing a chip-level JTAG-compliant test interface; and
means for scheduling test operations for the cores.

21. The MCC of claim 20, wherein the means for implementing a core-level JTAG-compliant test interface comprises a core-level test access port (TAP) controller.

22. The MCC of claim 21, wherein each core further comprises:
a number of testable circuits, each having a corresponding test controller; and
means for scheduling the test operations for the testable circuits.

23. The MCC of claim 22, wherein the means for scheduling the test operations for the testable circuits comprises a core-level master test controller coupled to each of the testable circuits.

24. The MCC of claim 23, wherein the testable circuits comprise built-in self test (BIST) enabled memory arrays, the corresponding test controller comprises a memory BIST controller, and the core-level master test controller comprises a master BIST controller.

25. The MCC of claim 21, wherein the means for implementing a chip-level JTAG-compliant test interface comprises a chip-level test access port (TAP) controller.

26. The MCC of claim 25, wherein the means for scheduling test operations for the cores comprises:
a chip-level master test controller coupled between the chip-level TAP controller and each of the cores.

27. The MCC of claim 26, wherein chip-level master test controller comprises a master built-in self test (BIST) controller.

28. The MCC of claim 25, wherein the chip-level TAP controller comprises a core select register for storing a plurality of core select bits, each indicating whether a corresponding core is selected for a test operation.

29. The MCC of claim 28, further comprising:
a plurality of core select pins to receive the core select bits; and
a test pin interface coupled to the plurality of core select pins and to the means for scheduling test operations for the cores.

30. The MCC of claim 28, wherein the chip-level TAP controller comprises a control mode register for storing a test mode bit indicating how the test operations are to be scheduled for the cores.

31. The MCC of claim 30, wherein the control mode register further stores an algorithm mode bit indicating which of a plurality of algorithms the test operation utilizes.

32. The MCC of claim 28, wherein each core comprises a microprocessor.

33. The MCC of claim 28, wherein each core further comprises gating logic coupled between the means for scheduling test operations for the cores and the core-level TAP controller, the gating logic selectively enabling the core for the test operations in response to the core select bits.
